(19) United States
(12) Patent Application Publication
(10) Pub. No.: US 2026/0262507 A1
(43) Pub. Date: Sep. 3, 2026

(54) GLASS SUBSTRATE FOR SEMICONDUCTOR AND METHOD FOR IDENTIFYING GLASS SUBSTRATE FOR SEMICONDUCTOR

(71) Applicant: AGC INC., Tokyo (JP)

(72) Inventors: Shinji UEKI, Tokyo (JP); Yoichiro SATO, Tokyo (JP)

(73) Assignee: AGC INC., Tokyo (JP)

(21) Appl. No.: 19/653,780

(22) Filed: Apr. 21, 2026

Related U.S. Application Data
(63) Continuation of application No. PCT/JP2024/035936, filed on Oct. 8, 2024.

(30) Foreign Application Priority Data
Oct. 25, 2023 (JP) 2023-183358

(51) Int. Cl. H10W 46/00; H10W 70/68; H10W 70/692

(52) U.S. Cl. CPC H10W 46/401; H10W 70/681; H10W 70/692

(57) ABSTRACT

A glass substrate for semiconductor according to an aspect of the present disclosure has a first main surface and a second main surface facing a direction opposite to that of the first main surface, and includes a plurality of holes formed on at least the first main surface. A number-based frequency distribution curve (horizontal axis: circle-equivalent diameter, vertical axis: number of holes) of circle-equivalent diameters of openings of the holes on the first main surface has at least one peak. The glass substrate for semiconductor has a hole of which the circle-equivalent diameter is out of a range of 95% to 105% of a class mark of any of the peaks.

### INCORPORATION BY REFERENCE

This application is based upon and claims the benefit of priority from Japanese patent application No. 2023-183358 filed on Oct. 25, 2023 and PCT application No. PCT/JP2024/035936 filed on Oct. 8, 2024, the disclosure of which is incorporated herein in its entirety by reference.

### BACKGROUND

The present disclosure relates to a glass substrate for semiconductor and a method for identifying a glass substrate for semiconductor.

In recent years, development of a technology for mounting a plurality of semiconductor chips on an insulating substrate and electrically connecting the plurality of semiconductor chips has been in progress. As the insulating substrate, glass substrates and resin substrates have been studied. The glass substrate is superior to the resin substrate in the flatness, the thermal stability, and the insulating property. The glass substrate has a first main surface and a second main surface facing a direction opposite to that of the first main surface, and includes a plurality of holes formed on at least the first main surface. For example, electrodes are to be embedded in the holes (see, for example, Patent Literatures 1 to 3).

[Patent Literature 1] Japanese Unexamined Patent Application Publication No. 2018-188351

[Patent Literature 2] Japanese U.S. Patent 7014068

[Patent Literature 3] Japanese Unexamined Patent Application Publication No. 2012-09106

### SUMMARY

An identifier is attached to the surface of such a glass substrate for semiconductor. The identifier is formed, for example, by laser processing. In the past, there have been cases where a plurality of glass substrates cannot be identified from one another because the identifiers inscribed in the glass substrates fade away in the process for cleaning the glass substrates.

In an aspect of the present disclosure, a technique capable of identifying a plurality of glass substrates for semiconductor is provided.

A glass substrate for semiconductor according to an aspect of the present disclosure has a first main surface and a second main surface facing a direction opposite to that of the first main surface, and includes a plurality of holes formed on at least the first main surface. A number-based frequency distribution curve (horizontal axis: circle-equivalent diameter, vertical axis: number of holes) of circle-equivalent diameters of openings of the holes on the first main surface has at least one peak. The glass substrate for semiconductor has a hole of which the circle-equivalent diameter is out of a range of 95% to 105% of a class mark of any of the peaks.

According to an aspect of the present disclosure, a plurality of glass substrates for semiconductor can be identified from one another based on the positions and number of holes of which the circle-equivalent diameters are out of a desired range.

The above and other objects, features and advantages of the present disclosure will become more fully understood from the detailed description given hereinbelow and the accompanying drawings.

### BRIEF DESCRIPTION OF DRAWINGS

FIG. 1 is a plan view showing a first main surface of a glass substrate according to an embodiment;

FIG. 2 is a cross-sectional view showing a glass substrate according to an embodiment;

FIG. 3 is a photomicrograph showing an example of a hole of which a part of the circular opening edge is missing;

FIG. 4 is a photomicrograph showing an example of a hole having a small circular opening edge;

FIG. 5 shows an example of a frequency distribution curve; and

FIG. 6 shows an example of a database.

### DESCRIPTION OF EMBODIMENTS

Embodiments according to the present disclosure will be described hereinafter with reference to the drawings. The same components or corresponding components are denoted by the same reference numerals (or symbols) throughout the drawings, and descriptions thereof may be omitted. In the specification, a symbol “−”, which indicates a range of numerical values, means that values in front of and behind this symbol are included in the range as lower and upper limit values, respectively. Numerical ranges include rounded-off ranges.

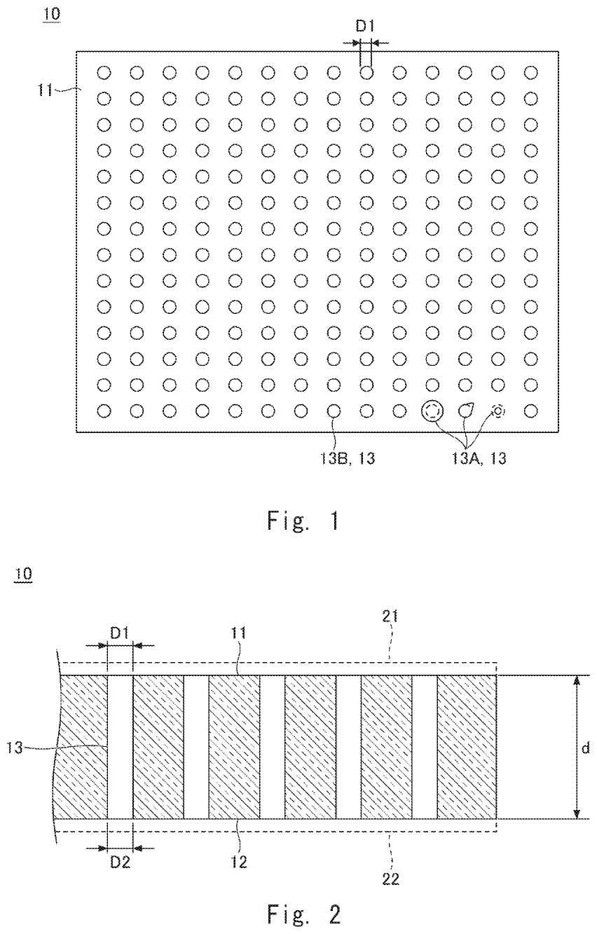

A glass substrate for semiconductor 10 according to an embodiment will be described with reference to FIGS. 1 and 2. Hereinafter, the glass substrate for semiconductor 10 will also be referred to simply as a glass substrate 10. Although the glass substrate 10 is used as a substrate on which semiconductor elements are mounted in this embodiment, it may be used as a substrate for passive elements or a probe guard substrate.

As shown in FIG. 2, the glass substrate 10 has a first main surface 11 and a second main surface 12 facing a direction opposite to that of the first main surface 11. Wiring layers 21 and 22 are to be formed on at least one of the first and second main surfaces 11 and 12. The wiring layer 21 is formed on the first main surface 11, and the wiring layer 22 is formed on the second main surface 12. Although the first and second main surfaces 11 and 12 have a rectangular shape in this embodiment, they may have a circular shape. Note that the rectangular shape includes a square shape.

The glass substrate 10 has rigidity higher than that of a resin substrate. Therefore, the warpage of the substrate can be reduced even when the areas (i.e., sizes) of the first and second main surfaces 11 and 12 are large. The area of each of the first and second main surfaces 11 and 12 is, for example, 1.0×10² mm² to 5.0×10⁵mm² , and preferably 7.0×10³ mm² to 3.0×10⁵ mm².

The glass material of the glass substrate 10 is not limited to any particular materials, but is, for example, an alkali-free glass, a quartz glass, or a photosensitive glass. An average coefficient of linear expansion of the glass material of the glass substrate 10 in a range of 5° C. to 200° C. is preferably in a range of 0.5×10⁻⁶/° C. to 13.0×10⁻⁶/° C. When the average coefficient of linear expansion is within the aforementioned range, the peeling of the wiring layers 21 and 22 can be suppressed.

The average value dave of the thickness d of the glass substrate 10 is, for example, 0.05 mm to 2.0 mm. The smaller the value dave is, the more easily the holes 13 can be formed. Further, the smaller the value dave is, the more the thickness of the semiconductor device can be reduced. The value dave is preferably 0.1 mm to 1.5 mm, and more preferably 0.2 mm to 1.2 mm.

As shown in FIG. 2, the glass substrate 10 includes holes 13 formed on at least one of the first and second main surfaces 11 and 12. Although the holes 13 are through holes formed through both the first and second main surfaces 11 and 12 in this embodiment, they may be non-through holes (bottomed holes) formed on only one of the first and second main surfaces 11 and 12. Further, both through holes and non-through holes may be formed in a mixed manner.

For example, an electrode electrically connected to at least one of the wiring layers 21 and 22 is to be embedded in at least one of the holes 13. In the case where the glass substrate 10 is used as an interposer, at least one of the holes 13 is a through hole, and a through electrode is to be embedded in the through hole. The through electrode electrically connects the wiring layer 21 with the wiring layer 22.

Note that at least one of the holes 13 may be a dummy hole in which no electrode is to be embedded. The dummy hole is formed in order to reduce the weight of the glass substrate 10 or prevent the warpage of the glass substrate 10. A hole in which an electrode is to be embedded may be hereinafter referred to as an electrode hole in order to distinguish it from a dummy hole.

The holes 13 are straight holes in this embodiment as shown in FIG. 2. The straight hole (e.g., each of the straight holes) has a constant diameter irrespective of the depth from the first main surface 11 or the second main surface 12. Note that the holes 13 may be tapered holes. The diameter of the tapered hole (e.g., each of the tapered holes) decreases as the depth from the first main surface 11 or the second main surface 12 increases.

Although not shown in the drawing, the hole 13 (e.g., one or each of the holes 13) may have a constriction at the middle thereof and may have two tapered holes on both sides of the constriction. The diameter of one of the two tapered holes decreases as the depth from the first main surface 11 increases. The diameter of the other tapered hole decreases as the depth from the second main surface 12 increases. Further, the hole 13 may be a hole in which a tapered hole and a straight hole are combined (i.e., connected).

When the hole 13 is a through hole and a straight hole, the circle-equivalent diameter D1 of the opening (i.e., the mouth) of the hole 13 on the first main surface 11 and the circle-equivalent diameter D2 of the opening of the hole 13 on the second main surface 12 are equal to each other. Note that the hole 13 may not be a straight hole, and the circle-equivalent diameters D1 and D2 may not be equal to each other. Either of the circle-equivalent diameters D1 and D2 may be larger than the other. The circle-equivalent diameter of the opening refers to the diameter of a circle having the area (i.e., the size) equal to that of the opening.

The circle-equivalent diameter D1 of the opening of the hole 13 (e.g., each of the holes 13) on the first main surface 11 is, for example, 10 μm to 300 μm. The circle-equivalent diameter D1 is preferably 20 μm to 200 μm, and more preferably 50 μm to 100 μm. Holes 13 having different circle-equivalent diameters D1 may be present in a mixed manner on the first main surface 11.

Similarly, the circle-equivalent diameter D2 of the opening of the hole 13 (e.g., each of the holes 13) on the second main surface 12 is, for example, 10 μm to 300 μm. The circle-equivalent diameter D2 is preferably 20 μm to 200 μm, and more preferably 50 μm to 100 μm. Holes 13 having different circle-equivalent diameters D2 may be present in a mixed manner on the second main surface 12.

In both the first and second main surfaces 11 and 12, the shape of the opening of the hole 13 (e.g., each of the holes 13) is preferably circular in view of the processability. However, the shape of the opening of the hole 13 is not limited to circular, and may be elliptical or polygonal. It is sufficient if the circle-equivalent diameters D1 and D2 of the opening of the hole 13 are 10 μm to 300 μm.

The ratio of the area (i.e., the size) of the opening of the hole 13 on the first main surface 11 to the total area of the first main surface 11 is, for example, 0.001% to 90%, preferably 0.07% to 80%, and more preferably 0.75% to 40%. Note that the total area of the first main surface 11 includes both the areas where the holes 13 are not present and the areas where the holes 13 are present. That is, the total area of the first main surface 11 includes the area of the openings of the holes 13 on the first main surface 11.

Similarly, the ratio of the area of the opening of the hole 13 on the second main surface 12 to the total area of the second main surface 12 is, for example, 0.001% to 90%, preferably 0.07% to 80%, and more preferably 0.75% to 40%. Note that the total area of the second main surface 12 includes both the areas where the holes 13 are not present and the areas where the holes 13 are present. That is, the total area of the second main surface 12 includes the areas of the openings of the holes 13 on the second main surface 12.

The number and arrangement of the holes 13 are not limited to those shown in FIG. 1. Although the holes 13 are arranged in a matrix pattern in FIG. 1, they may be arranged in a staggered pattern or may be randomly arranged. The number and arrangement of the holes 13, especially the number and arrangement of the electrode holes, are selected as appropriate according to the wiring patterns in the wiring layers 21 and 22.

The method for forming holes 13 may be an ordinary method, but in this embodiment, it is an ablation process. In the ablation process, the glass is locally evaporated or sublimated at the irradiation point of the laser beam, so that the part of the glass is locally removed. As compared with the drilling process, the occurrence of defects can be suppressed. The defects are, for example, fractures or cracks.

The light source for the ablation process may be either a CW (continuous wave) laser or a pulsed laser, but is preferably a pulsed laser. The pulsed laser is, for example, a CO₂ laser, a YAG laser, a UV laser, or an ArF excimer laser. The pulsed laser may be a femtosecond laser or a picosecond laser.

Note that the method for forming holes 13 may be an ordinary method as described above. For example, the method for forming holes 13 may be a drilling process, an etching process, or a blasting process. Laser processing and an etching process may be combined. A modified part is formed by modifying a part of the glass substrate in the laser processing, and then the modified part is preferentially etched in the etching process.

After the holes 13 are formed, an annealing process may be performed. The annealing process is a process for removing stresses remaining in the glass substrate 10 by heating the glass substrate 10.

As shown in FIG. 1, the glass substrate 10 has a plurality of holes 13 on at least the first main surface 11. Among the plurality of holes 13, some holes 13A have openings (i.e., the mouths) different from those of the remaining holes 13B on the first main surface 11. Some holes 13A are holes for identification, and the remaining holes 13B are electrode holes or dummy holes. Note that although not shown in the drawing, among the plurality of holes 13, some holes 13A may have openings (i.e., the mouths) different from those of the remaining holes 13B on the second main surface 12.

For example, as shown in FIGS. 1 and 3, a part of the circular opening edge of a hole for identification 13A may be missing and a part of the opening edge may extend radially outward. For example, by shifting the irradiation position of the laser beam when a hole for identification 13A is formed, it is possible to form a hole 13A of which a part of the circular opening edge is missing and a part of the opening edge extends radially outward as shown in FIG. 3.

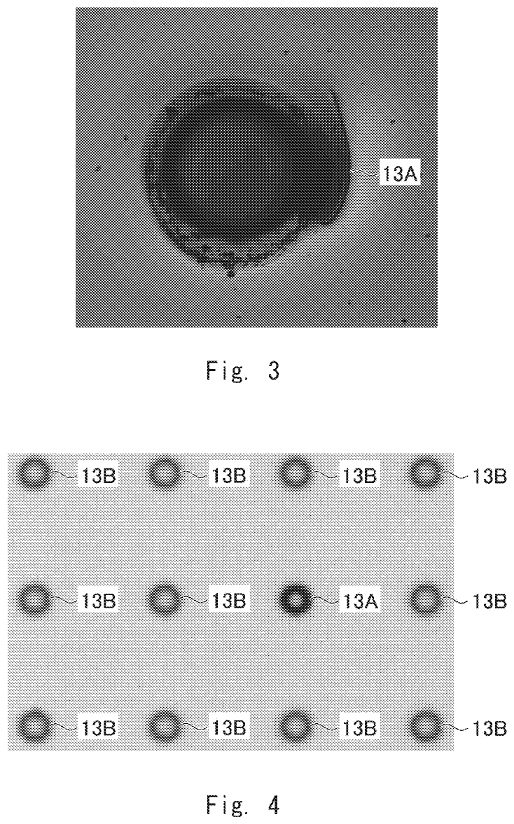

Alternatively, as shown in FIGS. 1 and 4, a hole for identification 13A may have a circular opening edge smaller than those of the remaining holes 13B. For example, by lowering the output of the laser beam when a hole for identification 13A is formed compared with the output that is applied when the remaining holes 13B are formed, it is possible to form a circular hole 13A smaller than the holes 13B.

Further, as shown in FIG. 1, a hole for identification 13A may have a circular opening edge larger than those of the remaining holes 13B. For example, by increasing the output of the laser beam when a hole for identification 13A is formed compared with the output that is applied when the remaining holes 13B are formed, it is possible to form a circular hole 13A larger than the holes 13B.

The hole(s) for identification 13A may be provided in, among n regions obtained by equally dividing the first main surface Il into n sections, only one region, a plurality of regions, or all the regions. n is, for example, a natural number of 2 to 100. When the first main surface 11 is rectangular, the n regions are arranged in a matrix pattern. In one glass substrate 10, the number of holes for identification 13A in one region may be equal to that in another region, or may be different therefrom. Further, a region(s) in which holes for identification 13A are provided in one glass substrate 10 may be the same as that of another glass substrate 10, or may be different therefrom.

While the holes for identification 13A can have opening edges having various shapes and various sizes on the first main surface 11, the remaining holes 13B have opening edges of a specific shape and a specific size on the first main surface 11.

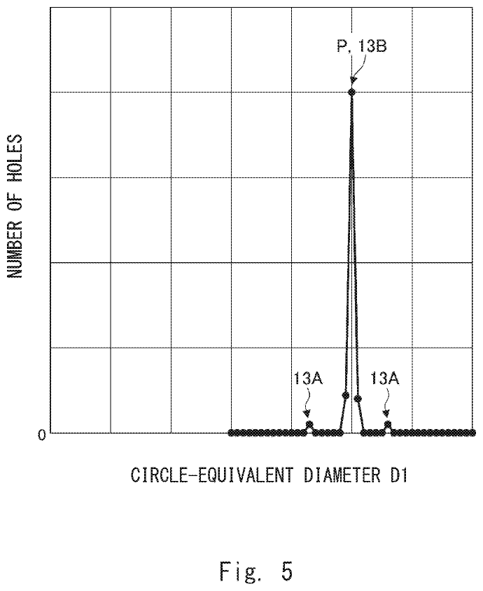

With reference to FIG. 5, an example of a number-based frequency distribution curve (horizontal axis: circle-equivalent diameter, vertical axis: number of holes) of circle-equivalent diameters DI of the openings of the holes 13 on the first main surface 11 will be described. The width of the class of the circle-equivalent diameter D1 is, for example, 1 μm. The frequency distribution curve has at least one peak P (one peak in this embodiment). Each of the at least one peak P is composed of 100 or more holes 13B. That is, the height of each peak P is 100 (holes) or more. Note that the height of the frequency distribution curve of the holes for identification 13A is less than 100 (preferably 70 or less, and more preferably 50 or less), so that it is not recognized as a peak but is recognized as a background. The number of holes for identification 13A may be less than 10% of the number of remaining holes 13B.

The circle-equivalent diameters D1 of the openings of the holes for identification 13A are preferably out of a range of 95% to 105% of the class mark of any of the peaks P. That is, the circle-equivalent diameters D1 of the openings of the holes for identification 13A are preferably out of a range of 95% to 105% of the class mark of any of all the peaks P. The class mark refers to the central value of each class. Note that the circle-equivalent diameters D1 of the openings of the remaining holes 13B are preferably in a range of 97% to 103% of one of the peaks P.

When the circle-equivalent diameters D1 of the openings of the holes for identification 13A are out of the range of 95% to 105% of the class mark of any of the peaks P, a difference between the circle-equivalent diameters D1 of the openings of the holes for identification 13A and the circle-equivalent diameters D1 of the openings of the remaining holes 13B is large, so that the holes for identification 13A can be easily distinguished from the remaining holes 13B. The circle-equivalent diameters D1 of the openings of the holes for identification 13A are more preferably out of a range of 90% to 110% of the class mark of any of the peaks P.

The circle-equivalent diameters D1 of the openings of the holes for identification 13A are preferably 80% or larger and smaller than 90%, or larger than 110% and 120% or smaller of the class mark of one of the peaks P. The difference between the circle-equivalent diameters D1 of the openings of the holes for identification 13A and the circle-equivalent diameters D1 of the openings of the remaining holes 13B is not too large, so that the holes for identification 13A and the remaining hole 13B can be formed by using the same processing machine. The circle-equivalent diameters D1 of the openings of the holes for identification 13A are more preferably 85% or larger and smaller than 90%, or 110% or larger and smaller 115% of the class mark of one of the peaks P.

A method for identifying a glass substrate 10 comprises identifying the glass substrate 10 based on the positions and number of holes for identification 13A. The positions and number of holes for identification 13A are unique to each glass substrate 10. Therefore, the glass substrate 10 can be identified based on the positions and number of holes for identification 13A. The positions and number of holes for identification 13A may be measured by using an image measuring system.

The image measuring system measures the position of each hole 13 and the circle-equivalent diameter D1 thereof by photographing the first main surface 11 of the glass substrate 10 after the holes 13 are formed and processing the obtained image. The light source for the photographing may be a transmission type or an incident-light type. The image processing comprises, for example, a binarization process. As the image measuring system, for example, NEXIV (product name) manufactured by Nikon Corporation can be used.

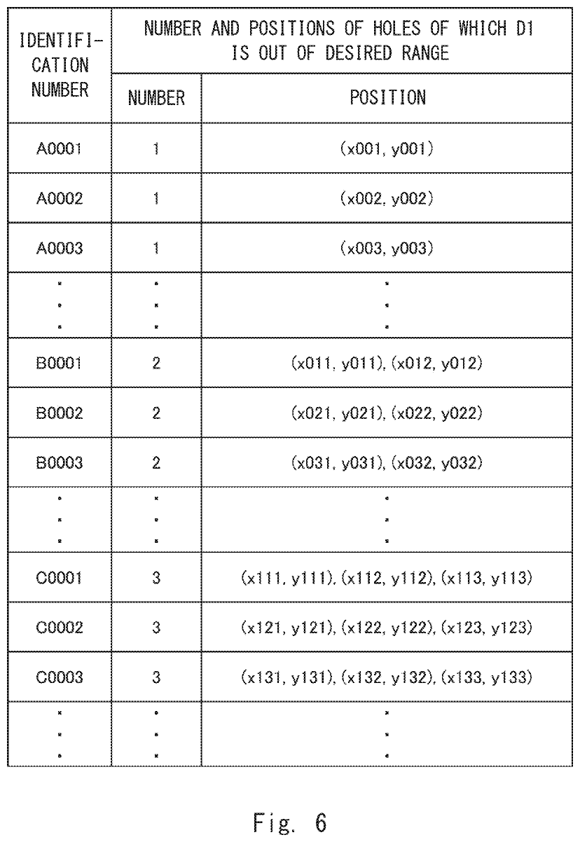

The image measuring system measures the position of each hole 13 and the circle-equivalent diameter D1 thereof, and creates a database as shown in FIG. 6. The database includes at least the number and positions of holes for identification 13A, and may further include identification numbers associated with these holes. However, the identification numbers may not be added. The number and positions of holes for identification 13A may be determined by using a numerical sequence such as an arithmetic progression, a geometric progression, or a difference sequence.

The method for identifying a glass substrate 10 may comprise identifying the glass substrate 10 based on the sizes of the holes for identification 13A in addition to the positions and number of the holes for identification 13A. In this case, the database includes the positions of the holes for identification 13A and the sizes of the holes for identification 13A in association with each other. The sizes of the holes 13A registered in the database may be the values of the circle-equivalent diameters D1 themselves, or may be only whether they are larger or smaller based on a desired range.

A glass substrate for semiconductor according to the present disclosure has been described above, but the present disclosure is not limited to the above-described embodiment. Various changes, modifications, substitutions, additions, deletions, and combinations are possible within the scope of the claims. Needless to say, they are also within the technical scope of the present disclosure.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A glass substrate for semiconductor having a first main surface and a second main surface facing a direction opposite to that of the first main surface, and includes a plurality of holes formed on at least the first main surface, wherein a number-based frequency distribution curve (horizontal axis:
circle-equivalent diameter, vertical axis: number of holes) of circle-equivalent diameters of openings of the holes on the first main surface has at least one peak, and
the circle-equivalent diameters of the openings of some holes among the plurality of holes are out of a range of 95% to 105% of a class mark of any of the peaks.

2. The glass substrate for semiconductor according to claim 1, wherein the circle-equivalent diameters of the openings of some holes among the plurality of holes are out of a range of 90% to 110% of a class mark of any of the peaks.

3. A method for identifying a glass substrate for semiconductor according to claim 1, comprising identifying the glass substrate for semiconductor based on positions and number of holes of which the circle-equivalent diameters are out of a range of 95% to 105% of a class mark of any of the peaks.
